(19) United States
(12) Patent Application Publication
(10) Pub. No.: US 2007/0194826 A1
(43) Pub. Date: Aug. 23, 2007

(54) CIRCUIT CAPABLE OF SELF-CORRECTING DELAY TIME AND METHOD THEREOF

(76) Inventors: Sen-Huang Tang, Hsinchu City (TW); Yi-Shu Chang, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/675,084

(22) Filed: Feb. 15, 2007

(30) Foreign Application Priority Data
Feb. 17, 2006 (TW) 095105396

(51) Int. Cl. H03L 7/00

(52) U.S. Cl. 327/161

(57) ABSTRACT

The present invention discloses a circuit capable of self-correcting delay time that includes a clock generating unit for generating a clock signal, a processing unit for producing a counter enable signal according to a reference clock, and a counting unit for receiving the counter enable signal and using the clock signal to count the reference clock for producing a count value, and the count value is returned to the processing unit for performing an analysis to obtain a delay time. The present invention can effectively overcome the shortcomings of the prior art that requires a delay circuit to make corrections one by one, and thus the invention can greatly save the time, manpower, and cost incurred.

### FIELD OF THE INVENTION

The present invention relates to a circuit and a method capable of self-correcting delay time, and more particularly, to a circuit and a method capable of self-correcting delay for overcoming the shortcomings of a conventional delay circuit, and thus the invention can greatly save the time, manpower, and cost incurred.

### BACKGROUND OF THE INVENTION

A computer system usually requires a reference signal (such as DQS) to latch a data stream of a data signal in the process of accessing a storage device (such as a dynamic random access memory, DRAM). Refer to FIG. 1 for the schematic circuit block diagram of a traditional delay circuit 10. After a reference signal DQS received by the delay circuit 10 passes through a comparator 11 and a delay chain 12, the reference signal DQS is converted into a corresponding trigger signal by a plurality of standard delay cells 13 of the delay chain 12, and the trigger signals are used for latching the data stream. The trigger signals outputted by the standard delay cells 13 correspond to a read phase and determine the quantity of delay cells 13 according to the required quantity of divided read phases. For example, four standard delay cells 13 in a delay chain 12 sequentially output the corresponding trigger signals for reading the phases at 90, 180, 270, and 360 degrees. If the quantity of the required divided read phases increases, then the quantity of delay cells 13 will increase accordingly, so that the cost and the required circuit area will be increased. Further, the design of the storage device requires repeated testing and trial-and-error experiments to determine a trigger signal applicable for the storage device to read the phase from the trigger signals outputted by the standard delay cells 13. Such traditional delay circuit 10 requires tremendous time, manpower and material cost for its design and mass production. Another prior art delay circuit employs an inverter delay to minimize the cost and circuit area, but the required delay value will not be accurate due to the process, voltage, and temperature (PVT). In addition, the environment of the printed circuit board (PCB) also will affect the accuracy of the delay value.

### SUMMARY OF THE INVENTION

Therefore, it is an objective of the present invention to provide a circuit capable of self correcting delay time and method thereof that include a delay circuit. The delay circuit comprises a processing unit, a counting unit, and a clock generating unit, wherein the delay circuit includes a reference clock with a known period in a chip. The counting unit includes at least a counter. The clock generating unit generates a clock signal with an unknown period and inputs the clock signal to the processing unit. When the processing unit is started by a counter enable signal produced by the reference clock, the processing unit sends the counter enable signal to the counting unit, so that the counting unit computes the reference clock and produce a count value. The count value is returned to the processing unit, so that the processing unit can analyze the count value to obtain a delay time. After the reference clock is changed, the delay circuit will process the abovementioned procedure, and the clock signal produced by a free run is used for computing the reference clock, so as to derive a relation between a minimum delay time unit and a corrected delay time required for reading the storage device. Regardless of the reference clock being changed due to actual design requirements or chip environments, the delay circuit can make a self-correction anytime to maintain the system stability. In the meantime, the present invention also can effectively overcome the problem of the prior art that requires the delay circuit to make corrections one by one, and thus the invention can greatly save the time, manpower, and cost incurred.

The above and other objects, features and advantages of the present invention will become apparent from the following detailed description taken with the accompanying drawings.

### BRIEF DESCRIPTION OF THE DRAWINGS

FIG. 1 is a schematic circuit diagram of a traditional delay circuit;

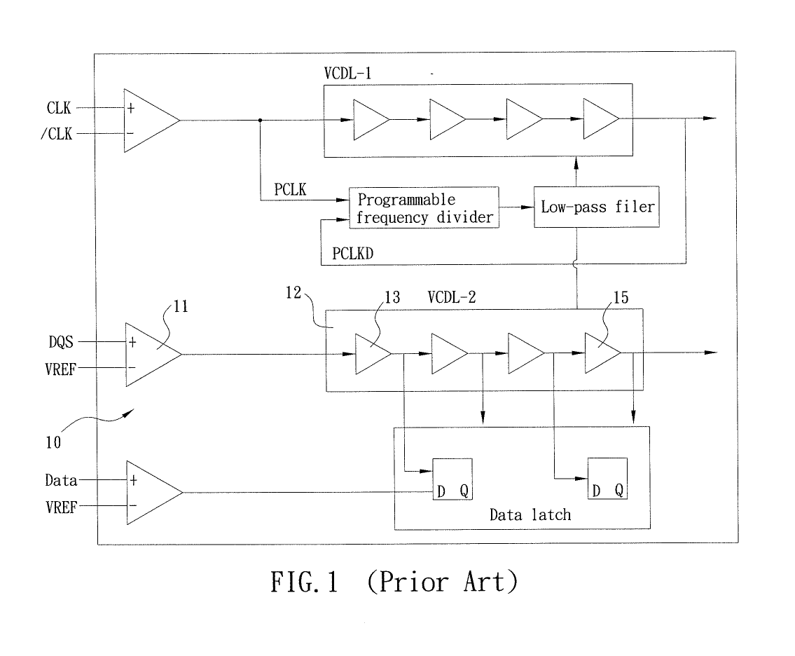

FIG. 2 is a schematic circuit block diagram of a delay circuit according to a first embodiment of the invention;

FIG. 3 is a schematic timing chart of a delay circuit of the invention; and

FIG. 4 is a schematic circuit block diagram of a delay circuit according to a second embodiment of the invention.

### DETAILED DESCRIPTION OF THE PREFERRED EMBODIMENTS

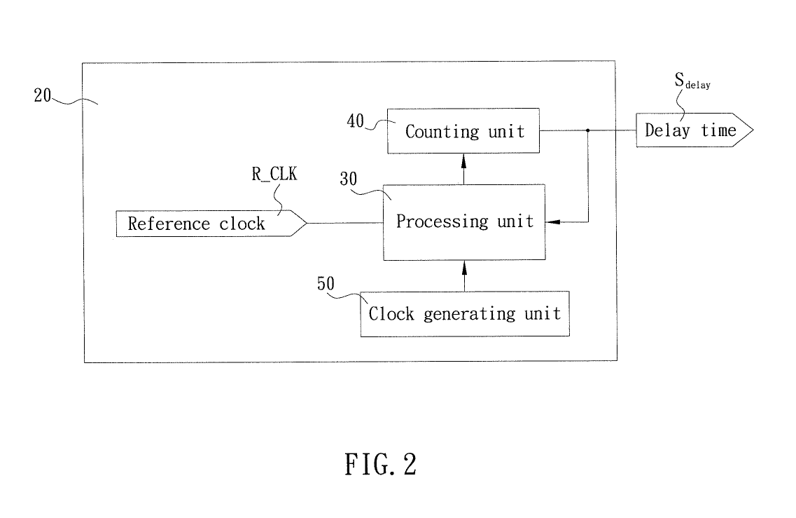

Referring to FIG. 2 for the circuit of self-correcting delay time and method thereof according to a first embodiment of the present invention, the delay circuit 20 includes a processing unit 30, a counting unit 40, and a clock generating unit 50. The delay circuit 20 includes a reference clock R_CLK with a known period (such as DQS) in a chip. The counting unit 40 includes at least one counter. In this embodiment, the clock generating unit 50 includes a plurality of delay cells for producing a clock signal D_CLK with an unknown period by a free run method, and then sending the clock signal D_CLK to the processing unit 30.

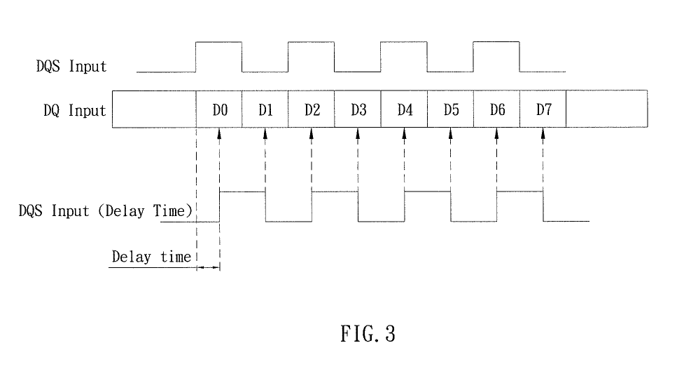

Referring to FIG. 3 for the schematic timing chart of the delay circuit 20 according to the embodiment of the invention, the processing unit 30 (as shown in FIG. 2) is enabled by a counter enable signal produced by the reference clock R_CLK. Then the processing unit 30 sends the counter enable signal to the counting unit 40, and the counting unit 40 uses the clock signal D_CLK with an unknown period to compute the reference clock R_CLK with a known period to produce a count value, so that a multiplicative relation exists between the clock signal D_CLK and the reference clock R_CLK. The count value will be returned to the processing unit 30, and thus the processing unit 30 can analyze the count value to obtain a delay time S_{delay}. For example, the reference clock R_CLK with a known period produces m periods, and a periodic time of the reference clock R_CLK is R_CLK_periodic, and the total count time is Enable_Time, then the following equation will be established:
Enable_Time=R_CLK-periodic*m Eq (1)

where m is a multiple of a periodic time of the reference clock R_CLK.

Referring to FIGS. 2 and 3, the following steps will take place for the computation after the processing unit 30 obtains a count result produced by the counting unit 40.

If a minimum delay time unit produced by the clock generating unit 50 is t_{delay}, then the following equation will be established for the clock signal D_CLK with an unknown period and the minimum delay time unit t_{delay}:
D_CLK periodic=2*t_{delay}*n Eq (2)

where n is a multiple of the minimum delay time t_{delay}.

If K is a count value produced by the clock signal D_CLK with an unknown period that counts the total count time Enable_Time, then Eq (2) is given below:
D_CLK periodic*K=2*t_{delay}*n*K Eq (3)
Eq (1) and Eq (3) are combined to obtain the following equation:
D_CLK_periodic*K=2*t_{delay}*n*K=Enable_Time=R_CLK_periodic*m Eq (4)

Therefore, the value of a minimum delay time unit can be derived and its equation is given below:
t_{delay}=(m/2 nK)*R_CLK-periodic Eq (5)

Referring to FIGS. 2 and 3 again, the processing unit 30 analyzes the foregoing computed result of Eq (5) and then results in the delay time S_{delay}required for latching the storage device, and the relation between the period R_CLK-periodic of the reference clock R_CLK and the S_{delay} is given below:
S_{delay}=R_CLK_periodic/T Eq (6)

where, T is a known coefficient. The equation for the relation between S_{delay} and t_{delay} can be derived as follows:
S_{delay}=D_CLK_periodic*K/(mT)=(2*t_{delay}*n)*K/(m*T) Eq (7)

On the other hand, if it is necessary to use J minimum delay time units t_{delay}to latch data, then S_{delay} can be set as J * t_{delay} directly, and the following equation can be obtained:
S_{delay}=J*t_{delay} Eq (8)

After the minimum delay time unit t_{delay} that will not be changed by process, voltage, and temperature (PVT) is obtained, the corrected delay time S_{delay} required for reading the storage device can be obtained.

Referring to FIGS. 2 and 3, if the reference clock R_CLK is changed, the delay circuit 20 will process according to the aforementioned procedure, and the clock signal D_CLK produced by free running is used to compute the reference clock R_CLK, and thus we can obtain the relation between a minimum delay time unit t_{delay} and a corrected delay time S_{delay} required for reading the storage device. Regardless of the reference clock being changed due to actual design requirements or chip environments, the delay circuit can make a self-correction anytime to maintain the system stability. In the meantime, the present invention also can effectively overcome the problem of the prior art that requires the delay circuit to make corrections one by one, and thus the invention can greatly save the time, manpower, and cost incurred.

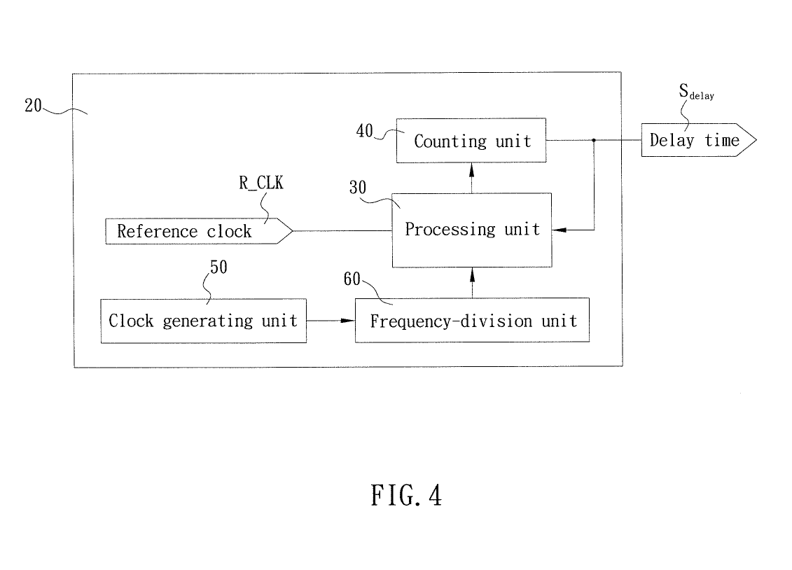

Referring to FIG. 4 for another embodiment of the present invention, the delay circuit 20 further comprises a frequency-division unit 60 coupled separately to the processing unit 30 and the clock generating unit 50. After the frequency-division unit 60 receives the clock signals D_CLK outputted from the clock generating unit 50 one by one, the frequency-division unit 60 will perform a frequency division for the received clock signal D-CLK and then will send the frequency-divided clock signal D_CLK to the processing unit 30, so as to reduce the period D_CLK_Periodic of the clock signal D_CLK received by the processing unit 30 and improve the accuracy of the delay circuit 20.

While the invention herein disclosed has been described by means of specific embodiments, numerous modifications and variations could be made thereto by those skilled in the art without departing from the scope and spirit of the invention set forth in the claims.

What is claimed is:

1. A circuit capable of self-correcting delay time, comprising:
a clock generating unit, for generating a clock signal;
a processing unit, for producing a counter enable signal according to a reference clock; and
a counting unit, for receiving said counter enable signal and computing said reference clock according to said clock signal to produce a count value;
wherein said count value is sent to said processing unit for performing an analysis to obtain a delay time.

2. The circuit of claim 1, wherein said clock generating unit generates said clock signal by a free run method.

3. The circuit of claim 1, further comprising a frequency-division unit for dividing the frequency of said clock signal and transmitting a frequency division result to said processing unit.

4. The circuit of claim 1, wherein said counting unit includes at least one counter.

5. The circuit of claim 1, wherein said delay time is the time required for latching a storage device.

6. The circuit of claim 1, wherein the reference clock is a DQS signal.

7. The circuit of claim 1, wherein the clock generating unit comprises a plurality of delay cells.

8. The circuit of claim 1, wherein the count value refers to a multiplicative relation between the clock signal and the reference clock.

9. The circuit of claim 1, wherein said delay time is the time required for latching a storage device.

10. A method for self-correcting delay time, comprising the steps of:
enabling a clock generating unit to produce a clock signal;
enabling a processing unit to generate a counter enable signal according to a reference clock;
enabling a counting unit by said counter enable signal,
counting said reference clock according to said clock signal for producing a count value; and
enabling said processing unit to analyze said count value for producing a delay time.

11. The method of claim 10 comprising:
generating said clock signal by a free run method.

12. The method of claim 10 comprising:
dividing the frequency of said clock signal; and providing the frequency divided clock signal to said counting unit to.

13. The method of claim 10, wherein said delay time is the time required for latching a storage device.

14. The method of claim 10, wherein the reference clock is a DQS signal.

15. The method of claim 10, wherein the step of producing a clock signal comprising:
utilizing a plurality of delay cells.

16. The method of claim 10, wherein the count value refers to a multiplicative relation between the clock signal and the reference clock.
